(19) United States
(12) Patent Application Publication
(10) Pub. No.: US 2026/0173681 A1
(43) Pub. Date: Jun. 18, 2026

(54) DISPLAY DEVICE AND METHOD FOR FABRICATING THE DISPLAY DEVICE

(71) Applicant: Samsung Display Co., LTD., Yongin-si (KR)

(72) Inventors: Yun Jong YEO, Yongin-si (KR); Chang Ho YI, Yongin-si (KR); Da Woon JUNG, Yongin-si (KR)

(21) Appl. No.: 19/279,464

(22) Filed: Jul. 24, 2025

(30) Foreign Application Priority Data
Dec. 12, 2024 (KR) 10-2024-0184576

(51) Int. Cl. H10K 59/131; G02B 27/01; H10H 29/01; H10H 29/41; H10H 29/49; H10K 59/12; H10K 59/124; H10K 77/10; H10K 102/00

(52) U.S. Cl. CPC H10K 59/131; G02B 27/0172; H10H 29/012; H10H 29/41; H10H 29/49; H10K 59/1201; H10K 59/124; H10K 77/111; G02B 2027/0178; H10K 2102/311

(57) ABSTRACT

A display device includes: a substrate comprising a conductive material; a first insulating layer disposed on the substrate; a first conductive layer connected to the conductive material through a first contact hole penetrating the first insulating layer; a second insulating layer disposed on the first conductive layer; and a second conductive layer connected to the first conductive layer through a second contact hole penetrating the second insulating layer, wherein the first conductive layer comprises a first connection metal layer, a first filling layer; and a first metal layer in contact with and covering the first connection metal layer and the first filling layer, wherein the first connection metal layer and the first filling layer are located inside the first contact hole, and wherein a thickness of the first connection metal layer and a thickness of the first filling layer are less than a height of the first contact hole.

This application claims priority to Korean Patent Application No. 10-2024-0184576, filed on Dec. 12, 2024, and all the benefits accruing therefrom under 35 U.S.C. § 119, the content of which in its entirety is herein incorporated by reference.

### BACKGROUND

### 1. Field

The present disclosure relates to a display device and a method for fabricating the display device.

### 2. Description of the Related Art

As the information-oriented society evolves, the demand for various display devices is ever increasing. For example, display devices are being employed by a variety of electronic devices such as, for example, smart phones, digital cameras, laptop computers, navigation devices, and smart televisions. Display devices may be flat panel display devices such as, for example, a liquid-crystal display device, a field emission display device, and an organic light-emitting display device. Among such flat panel display devices, a light-emitting display device includes a light-emitting element that can emit light on its own, such that each of the pixels of the display panel can emit light by themselves. Accordingly, a light-emitting display device can display images without a backlight unit for supplying light to the display panel.

### SUMMARY

Aspects of the present disclosure provide a display device that can provide high-resolution images and a method for fabricating a display device.

Aspects of the present disclosure provide a high-resolution display device in which a plurality of conductive layers can be disposed in a minimum area, and the conductive layers can be in stable contact with each other.

It should be noted that objects of the present disclosure are not limited to the above-mentioned object; and other objects of the present disclosure will be apparent to those skilled in the art from the following descriptions.

In an embodiment of the disclosure, a display device includes: a substrate including a conductive material; a first insulating layer disposed on the substrate; a first conductive layer connected to the conductive material through a first contact hole penetrating the first insulating layer; a second insulating layer disposed on the first conductive layer; and a second conductive layer connected to the first conductive layer through a second contact hole penetrating the second insulating layer, wherein the first conductive layer includes a first connection metal layer, a first filling layer, and a first metal layer in contact with and covering the first connection metal layer and the first filling layer, wherein the first connection metal layer and the first filling layer are located inside the first contact hole, and wherein a thickness of the first connection metal layer and a thickness of the first filling layer are less than a height of the first contact hole.

In an embodiment, the thickness of the first connection metal layer and the thickness of the first filling layer have values that may range from 70% to less than 100% of the height of the first contact hole.

In an embodiment, the first insulating layer may include a first surface facing the second insulating layer and a side surface facing the first contact hole, and wherein the first connection metal layer is in contact with the side surface of the first insulating layer but is not in contact with the first surface of the first insulating layer.

In an embodiment, the first metal layer may be in contact with the first surface and the side surface of the first insulating layer.

In an embodiment, the first metal layer and the first connection metal layer may be in contact with each other in the first contact hole, and wherein the first metal layer and the first connection metal layer are electrically connected with each other.

In an embodiment, the first filling layer may be entirely surrounded by the first metal layer and the first connection metal layer in a cross-section.

In an embodiment, the second conductive layer may be in contact with a first connecting portion of the first metal layer, and the first connecting portion overlaps with the first contact hole and the second contact hole in a direction perpendicular to the substrate.

In an embodiment, the second conductive layer may include a second connection metal layer and a second filling layer located in the second contact hole; and a second metal layer in contact with and covering the second connection metal layer and the second filling layer, wherein the second connection metal layer is connected to the first metal layer through the first connecting portion.

In an embodiment, the display device may include a via layer disposed on the second conductive layer; and a third conductive layer connected to the second conductive layer through a third contact hole penetrating the via layer, wherein the third conductive layer is in contact with a second connecting portion of the second metal layer, and wherein the first connecting portion and the second connecting portion overlap with each other in the direction perpendicular to the substrate.

In an embodiment, the display device may further include an anode electrode disposed on the via layer, wherein the third conductive layer is in contact with the anode electrode through an anode contact hole.

In an embodiment, the first connection metal layer may define an opening overlapping with the first contact hole when viewed from above, and wherein the first connection metal layer exposes the first filling layer in the opening when viewed from above.

In an embodiment, the first connection metal layer may completely surround the first filling layer when viewed from above.

In an embodiment, the first connection metal layer and the first filling layer may be located in the first contact hole when viewed from above.

In an embodiment of the disclosure, a method for fabricating a display device includes: forming a contact hole penetrating an insulating layer covering a substrate and then forming a connection metal layer on the insulating layer; forming a filling layer on the connection metal layer and then performing a first etch-back process which removes a part of the filling layer; performing a second etch-back process which removes a part of the connection metal layer; and forming a metal layer on the connection metal layer and the filling layer.

In an embodiment, portions of the filling layer that do not overlap with the contact hole may be completely removed via the first etch-back process without any mask.

In an embodiment, portions of the connection metal layer that do not overlap with the contact hole may be completely removed via the second etch-back process without any mask.

In an embodiment, a thickness of the connection metal layer and a thickness of the filling layer may have values ranging from 70% to less than 100% of a height of the contact hole, and wherein the metal layer entirely covers the connection metal layer and the filling layer.

In an embodiment of the disclosure, an electronic device includes: at least one display device including a substrate including a conductive material; a display device housing in which the at least one display device is accommodated; and an optical member which magnifies displayed images of the at least one display device or converts a light path of the displayed images, wherein the at least one display device includes: a first insulating layer disposed on the substrate; a first conductive layer connected to the conductive material through a first contact hole penetrating the first insulating layer; a second insulating layer disposed on the first conductive layer; and a second conductive layer connected to the first conductive layer through a second contact hole penetrating the second insulating layer, wherein the first conductive layer includes: a first connection metal layer, a first filling layer, and a first metal layer in contact with and covering the first connection metal layer and the first filling layer, wherein the first connection metal layer and the first filling layer are located inside the first contact hole, and wherein a thickness of the first connection metal layer and a thickness of the first filling layer are less than a height of the first contact hole.

According to the embodiments of the present disclosure, a high-resolution display device can be provided. In some aspects, a plurality of conductive layers can be disposed in a minimum area in a display device, and the conductive layers can be in stable contact with each other.

It should be noted that effects of the present disclosure are not limited to those described herein and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a head-mounted electronic device according to an embodiment of the present disclosure.

FIG. 2 is an exploded perspective view illustrating an example of the head-mounted electronic device of FIG. 1.

FIG. 3 is a perspective view illustrating a head-mounted electronic device according to an embodiment of the present disclosure.

FIG. 4 is a perspective view illustrating a display device according to an embodiment.

FIG. 5 is a cross-sectional view illustrating a display device according to an embodiment of the present disclosure.

FIG. 6 is a plan view illustrating a display layer of a display device according to an embodiment of the present disclosure.

FIG. 7 is a cross-sectional view illustrating an example of the display layer taken along line X-X′ of FIG. 6.

FIG. 8 is an enlarged cross-sectional view of area A of FIG. 7.

FIG. 9 is an enlarged cross-sectional view of the first conductive layer of FIG. 8.

FIG. 10 is an enlarged plan view of the first conductive layer of FIG. 8.

FIG. 11 is a flowchart for illustrating a method for fabricating the first conductive layer in FIG. 7.

FIGS. 12 and 13 are cross-sectional views illustrating step S100 of FIG. 11.

FIGS. 14 to 16 are cross-sectional views illustrating step S200 of FIG. 11.

FIGS. 17 and 18 are cross-sectional views illustrating step S300 of FIG. 11.

FIG. 19 is a cross-sectional view illustrating step S400 of FIG. 11.

FIG. 20 is a block diagram of an electronic device according to an embodiment of the present disclosure.

FIG. 21 is a view illustrating electronic devices according to a variety of embodiments of the present disclosure.

### DETAILED DESCRIPTION

Embodiments of the disclosure now will be described more fully hereinafter with reference to the accompanying drawings, in which various embodiments are illustrated. Aspects supported by the present disclosure may, however, be embodied in many different forms, and should not be construed as limited to the embodiments set forth herein. Rather, the example embodiments are provided such that this disclosure will be thorough and complete, and will fully convey the scope of example aspects of the present disclosure to those skilled in the art. Like reference numerals refer to like elements throughout.

It will be understood that when an element is referred to as being “on” another element, it may be directly on the other element or intervening elements may be therebetween. In contrast, when an element is referred to as being “directly on” another element, there are no intervening elements present.

It will be understood that, although the terms “first,” “second,” “third,” and the like may be used herein to describe various elements, components, regions, layers and/or sections, these elements, components, regions, layers and/or sections should not be limited by these terms. These terms are used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as, for example, “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” may mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel. The term “substantially identical” means approximately or actually identical.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments of the present disclosure will be described in detail with reference to the accompanying drawings.

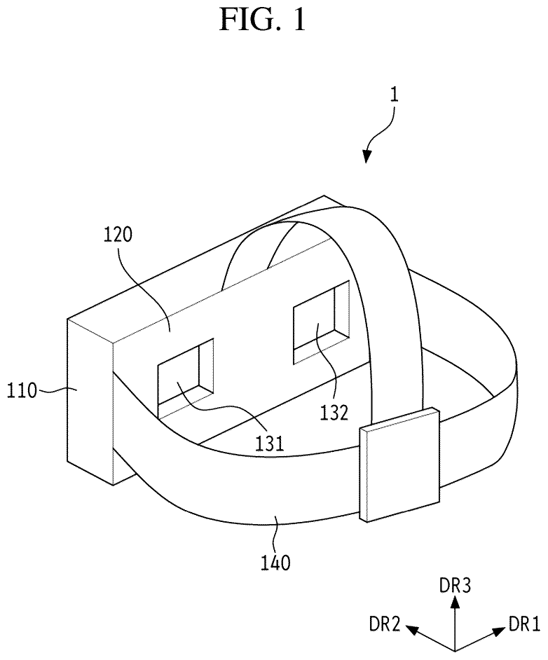

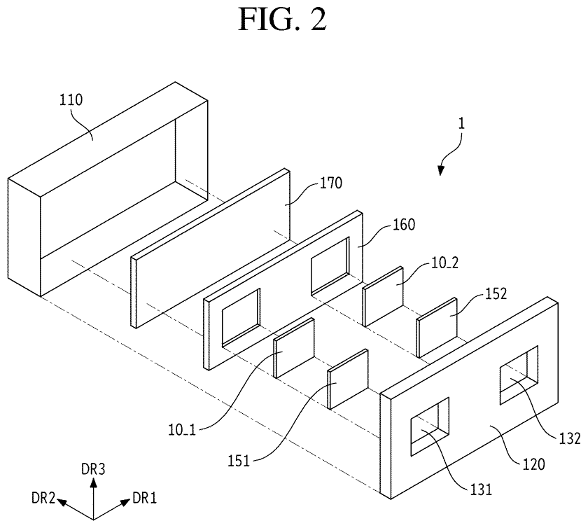

FIG. 1 is a perspective view illustrating a head-mounted electronic device according to an embodiment of the present disclosure. FIG. 2 is an exploded perspective view illustrating an example of the head-mounted electronic device of FIG. 1.

Referring to FIGS. 1 and 2, the head-mounted electronic device 1 according to an embodiment includes a display device housing 110, a housing cover 120, a first eyepiece 131, a second eyepiece 132, a head strap band 140, a first display device 10_1, a second display device 10_2, a middle frame 160, a first optical member 151, a second optical member 152, a control circuit board 170, and a connector.

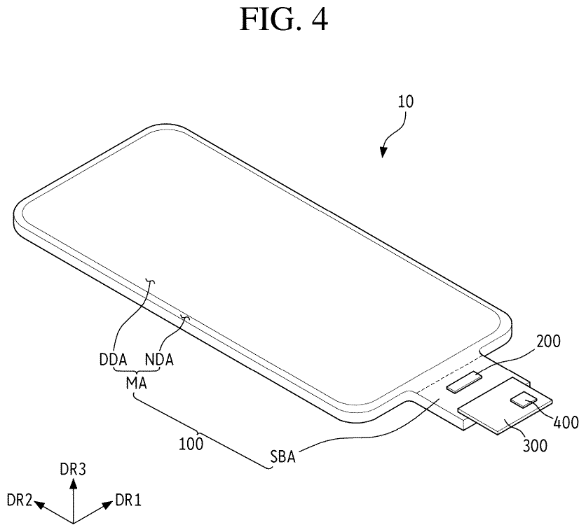

The first display device 10_1 provides images to a user's left eye, and the second display device 10_2 provides images to the user's right eye. Each of the first display device 10_1 and the second display device 10_2 is substantially identical to the display device 10 described with reference to FIG. 4. Therefore, descriptions of the first display device 10_1 and the second display device 10_2 will be replaced with descriptions with reference to FIG. 4.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170, and may be disposed between the second display device 10_2 and the control circuit board 170. The middle frame 160 serves to support and fix the first display device 10_1, the second display device 10_2 and the control circuit board 170.

The control circuit board 170 may be disposed between the middle frame 160 and the display device housing 110. The control circuit board 170 may be connected to the first display device 10_1 and the second display device 10_2 through a connector. The control circuit board 170 may convert an image source input from the outside into digital video data (DATA) and may transmit the digital video data (DATA) to the first display device 10_1 and the second display device 10_2 through the connector.

The control circuit board 170 may transmit digital video data (DATA) associated with a left eye image optimized for the user's left eye to the first display device 10_1, and may transmit digital video data (DATA) associated with a right eye image optimized for the user's right eye to the second display device 10_2. Alternatively, the control circuit board 170 may transmit the same digital video data (DATA) to the first display device 10_1 and the second display device 10_2.

The display device housing 110 accommodates the first display device 10_1, the second display device 10_2, the middle frame 160, the first optical member 151, the second optical member 152, the control circuit board 170, and the connector. The housing cover 120 is disposed to cover the open face of the display device housing 110. The housing cover 120 may include the first eyepiece 131 where the user's left eye is placed, and the second eyepiece 132 where the user's right eye is placed. Although the first eyepiece 131 and the second eyepiece 132 are separately disposed in the example illustrated in FIGS. 1 and 2, the embodiments of the present disclosure are not limited thereto. The first eyepiece 131 and the second eyepiece 132 may be combined into a single element.

The first eyepiece 131 may be aligned with the first display device 10_1 and the first optical member 151, and the second eyepiece 132 may be aligned with the second display device 10_2 and the second optical member 152. Therefore, a user may see virtual images of images on the first display device 10_1 magnified by the first optical member 151 through the first eyepiece 131, and virtual images of images on the second display device 10_2 magnified by the second optical member 152 through the second eyepiece 132.

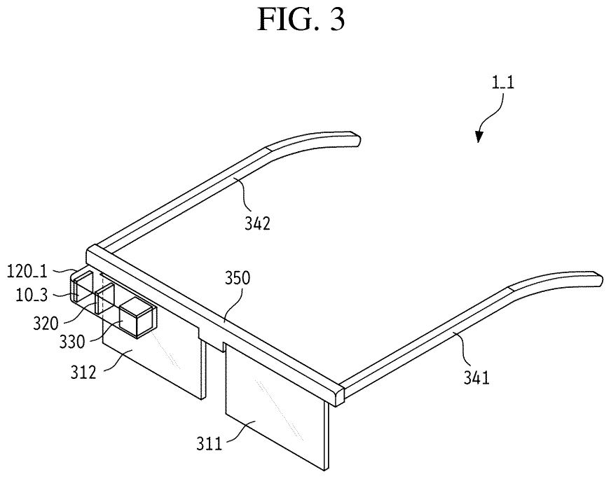

The head strap band 140 fixes the display device housing 110 to the user's head such that the first eyepiece 131 and the second eyepiece 132 of the housing cover 120 remain in line with the user's left and right eyes, respectively. By implementing a display device housing 110 which is light and small, the head-mounted electronic device 1 may include an eyeglasses frame as illustrated in FIG. 3 instead of a head strap band 140.

In some aspects, the head-mounted electronic device 1 may further include a battery for supplying power, an external memory slot for inserting an external memory, and an external connection port and a wireless communication module for receiving an image source. The external connection port may be a USB (universe serial bus) terminal, a display port, or an HDMI (high-definition multimedia interface) terminal. The wireless communication module may be a 5G communication module, a 4G communication module, a Wi-Fi module, or a Bluetooth module.

FIG. 3 is a perspective view illustrating a head-mounted electronic device according to an embodiment of the present disclosure.

Referring to FIG. 3, the head-mounted electronic device 1_1 according to the embodiment may be a glasses-type display device with a display device housing 120_1 which is light and small. The head-mounted electronic device 1_1 according to the embodiment may include a display device 10_3, a left-eye lens 311, a right-eye lens 312, a support frame 350, eyeglass temples 341 and 342, an optical member 320, a light path conversion member 330, and a display device housing 120_1.

The display device 10_3 illustrated in FIG. 3 is substantially identical to the display device 10 described with reference to FIG. 4.

The display device housing 120_1 may include the display device 10_3, the optical member 320, and the light path conversion member 330. The images displayed on the display device 10_3 may be enlarged by the optical member 320, and the light path of the images are converted by the light path conversion member 330 to be provided to the user's right eye through the right-eye lens 312. As a result, the user can see, with the right eye, augmented reality images that combine virtual images displayed on the display device 10_3 and real world images viewed through the right-eye lens 312.

Although the display device housing 120_1 is disposed at the right end of the support frame 350 in the example illustrated in FIG. 3, the embodiments of the present disclosure are not limited thereto. For example, the display device housing 120_1 may be disposed at the left end of the support frame 350. In such case, images displayed on the display device 10_3 may be provided to the user's left eye. Alternatively, the display device housing 120_1 may be disposed at both the left and right ends of the support frame 350, respectively. In such case, the user can watch images displayed on the display device 10_3 through both the left and right eyes.

FIG. 4 is a perspective view illustrating a display device according to an embodiment.

Referring to FIG. 4, a display device 10 may be employed by portable electronic devices such as, for example, a mobile phone, a smart phone, a tablet PC, a mobile communications terminal, an electronic notebook, an electronic book, a portable multimedia player (PMP), a navigation device and an ultra mobile PC (UMPC). For example, the display device 10 may be used as a display unit of a television, a laptop computer, a monitor, an electronic billboard, or the Internet of Things (IoT). In another example, the display device 10 may be applied to wearable devices such as, for example, a smart watch, a watch phone, a glasses-type display, and a head-mounted display (HMD) device.

The display device 10 may have a shape similarly to a quadrangular shape when viewed from above. For example, the display device 10 may have a shape similar to a rectangle having shorter sides in a first direction DR1 and longer sides in a second direction DR2. The corners where the shorter sides in the first direction DR1 meet the longer sides in the second direction DR2 may be rounded with a predetermined curvature or may be a right angle. The shape of the display device 10 when viewed from above is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA. The main area MA may include the display area DDA including pixels for displaying images, and the non-display area NDA located around the display area DDA.

The display area DDA may output light from a plurality of emission areas or a plurality of openings to be described later. For example, the display panel 100 may include pixel circuits including switching elements, a pixel-defining layer that defines the emission areas or the openings, and self-light-emitting elements. For example, the self-light-emitting element may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED). In the following drawings, it is illustrated that the self-luminous element is an organic light-emitting diode.

The non-display area NDA may be disposed on the outer side of the display area DDA. The non-display area NDA may be defined as the edge area of the main area MA of the display panel 100.

The subsidiary area SBA may be extended from one side of the main area MA. The subsidiary area SUB may include a flexible material that can be bent, folded, or rolled. In an example in which the subsidiary area SBA is bent, the subsidiary area SBA may overlap the main area MA in the thickness direction (e.g., third direction DR3). The subsidiary area SBA may include pads connected to the display driver 200 and the circuit board 300. According to another embodiment, the subsidiary area SBA may be eliminated, and the display driver 200 and the pads may be disposed in the non-display area NDA.

The display driver 200 may output signals and voltages for driving the display panel 100. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be located in the subsidiary area SBA and may overlap with the main area MA in the thickness direction as the subsidiary area SBA is bent. In another example, the display driver 200 may be mounted on the circuit board 300.

The circuit board 300 may be attached on the pad area of the display panel 100 using an anisotropic conductive film (ACF). The circuit board 300 may be a flexible printed circuit board (FPCB), a printed circuit board (PCB), or a flexible film such as, for example, a chip-on-film (COF).

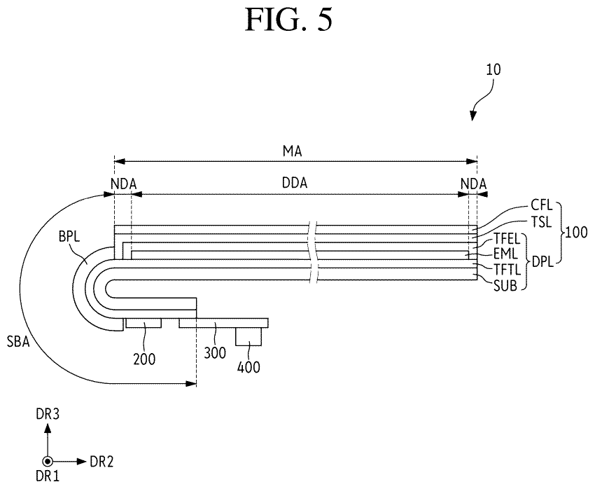

The touch driver 400 may be mounted on the circuit board 300. The touch driver 400 may be connected to a touch sensor layer TSL (see FIG. 5) for detecting and driving a touch on the display device 10.

FIG. 5 is a cross-sectional view illustrating a display device according to an embodiment of the present disclosure.

Referring to FIG. 5, the display panel 100 may include a display layer DPL, a touch sensor layer TSL, and a color filter layer CFL. The display layer DPL may include a substrate SUB, a transistor layer TFTL, a display element layer EML, and a thin-film encapsulation layer TFEL.

The substrate SUB may be a base substrate or a base member. The substrate SUB may be a flexible substrate that can be bent, folded, or rolled. For example, the substrate SUB may include, but is not limited to, a polymer resin such as, for example, polyimide PI. According to another embodiment, the substrate SUB may include a glass material or a metal material.

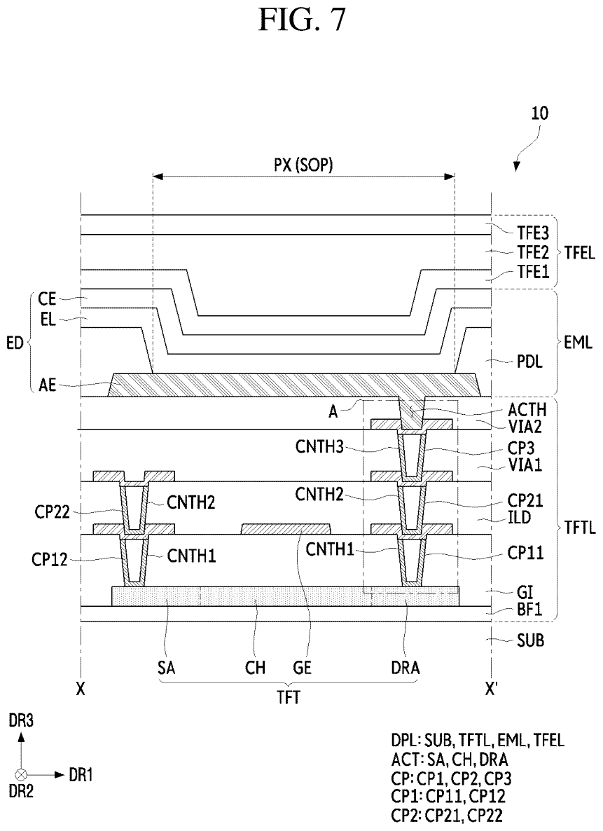

The transistor layer TFTL may be disposed on the substrate SUB. The transistor layer TFTL may be located in the display area DDA, the non-display area NDA and the subsidiary area SBA. The transistor layer TFTL may include a plurality of transistors TFT (see FIG. 7).

The display element layer EML may be disposed on the transistor layer TFTL. The display element layer EML may be located in the display area DDA. The display element layer EML may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

The thin-film encapsulation layer TFEL may be located on the display element layer EML. The thin-film encapsulation layer TFEL may be located in the display area DDA and the non-display area NDA. The thin-film encapsulation layer TFEL may cover the upper and side surfaces of the display element layer EML, and can protect the display element layer EML from outside oxygen and moisture. The thin-film encapsulation layer TFEL may include at least one inorganic film and at least one organic film for encapsulating the display element layer EML. The thin-film encapsulation layer TFEL may be eliminated in some implementations.

The touch sensor layer TSL may be disposed on the thin-film encapsulation layer TFEL. The touch sensor layer TSL may be located across the display area DDA and the non-display area NDA. The touch sensor layer TSL may sense a user's touch by mutual capacitance sensing or self-capacitance sensing. The touch sensor layer TSL may be eliminated in some implementations.

The color filter layer CFL may be disposed on the touch sensor layer TSL. The color filter layer CFL may be located in the display area DDA and the non-display area NDA. The color filter layer CFL may absorb some of lights introduced from the outside of the display device 10 to reduce the reflection of external light. Accordingly, the color filter layer CFL can prevent distortion of colors due to the reflection of external light.

Since the color filter layer CFL is disposed directly on the touch sensor layer TSL, the display device 10 may be implemented without a separate substrate for the color filter layer CFL. Therefore, the thickness of the display device 10 can be relatively small. The color filter layer CFL may be eliminated in some implementations.

As illustrated in FIG. 5, a portion of the display panel 100 overlapping with the subsidiary area SBA may be bent. In an example in which a portion of the display panel 100 is bent, the display driver 200, the circuit board 300 and the touch driver 400 may overlap with the main area MA in the third direction DR3.

When a part of the display panel 100 is bent, the bending protection layer BPL can protect the underlying structures located in the subsidiary area SBA from bending stress.

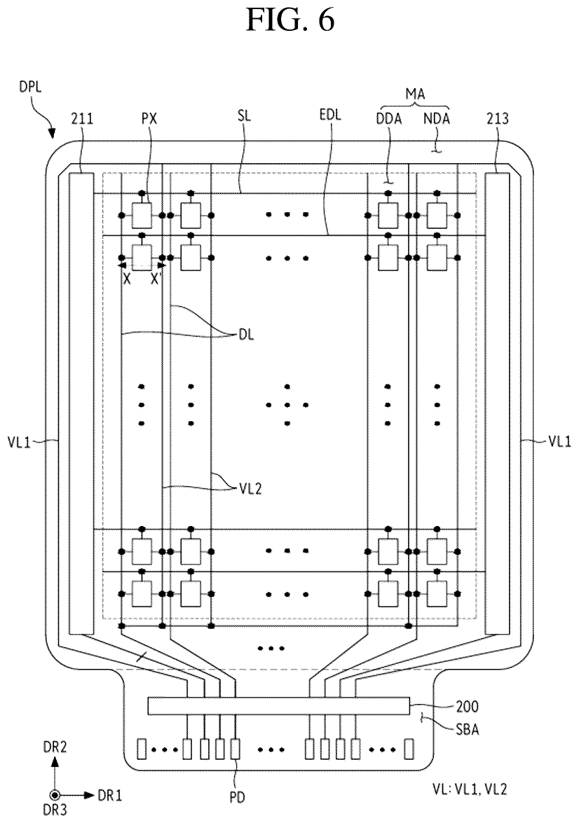

FIG. 6 is a plan view illustrating a display layer of a display device according to an embodiment of the present disclosure.

Referring to FIG. 6, the display layer DPL may include a plurality of pixels PX located in the display area DDA, and a plurality of voltage lines VL, a plurality of scan lines SL, a plurality of emission control lines EDL and a plurality of data lines DL connected to the plurality of pixels PX.

The plurality of scan lines SL may be extended in the first direction DR1 and may be spaced apart from one another in the second direction DR2 intersecting the first direction DR1. The scan lines may be arranged along the second direction DR2. The scan lines SL may sequentially supply a scan signal to the pixels PX.

The emission control lines EDL may be extended in the first direction DR1 and may be spaced apart from one another in the second direction DR2. The emission control lines EDL may be arranged along the second direction DR2. The emission control lines EDL may sequentially supply an emission control signal to the pixels PX.

The data lines DL may be extended in the second direction DR2 and may be spaced apart from one another in the first direction DR1. The data lines DL may be arranged along the first direction DR1. The data lines DL may apply data voltage to the pixels PX. The data voltage may determine the luminance of each of the plurality of pixels PX.

The voltage lines VL may include a main voltage line VL1 and a subsidiary voltage line VL2. At least one of the first supply voltage (high-level voltage) or the second supply voltage (low-level voltage) may be transmitted to the subsidiary voltage line VL2 through the main voltage line VL1 located in the non-display area NDA. In the following descriptions, the main voltage line VL1 and the subsidiary voltage line VL2 may be collectively referred to as voltage lines VL.

The non-display area NDA may surround the display area DDA. The non-display area NDA may include a scan driver 211, an emission control driver 213.

The scan driver 211 may be disposed on an outer side of the display area DDA or on a side of the non-display area NDA. The scan driver 211 may include a plurality of driving transistors for generating gate signals based on a gate control signal.

The emission control driver 213 may be disposed on the opposite outer side of the display area DDA or on the opposite side of the non-display area NDA. The emission control driver 213 may include a plurality of emission control transistors for generating emission signals based on the emission control signal.

The display layer DPL according to the embodiment may include the display driver 200 and a plurality of pad electrodes PD located in the subsidiary area SBA. The plurality of pad electrodes PD may be spaced apart from one another in the first direction DR1, and the pad electrodes PD may be connected to different lines, respectively.

FIG. 7 is a cross-sectional view illustrating an example of the display layer DPL taken along line X-X′ of FIG. 6. FIG. 7 is a cross-sectional view illustrating an example of the display layer DPL included in a pixel PX, and schematically illustrates the substrate SUB, the transistor layer TFTL, the display element layer EML, and the thin-film encapsulation layer TFEL. The substrate SUB has been described herein with reference to FIG. 5; and, therefore, redundant descriptions thereof will be omitted.

Referring to FIG. 7 in conjunction with FIGS. 1 to 6, the transistor layer TFTL may be disposed on the substrate SUB.

The transistor layer TFTL may be disposed on the substrate SUB. The transistor layer TFTL may include a buffer layer BF, a transistor TFT, a first insulating layer GI, a first conductive layer CP1, a second insulating layer ILD, a second conductive layer CP2, a first via layer VIA1, a third conductive layer CP3, and a second via layer VIA2.

The buffer layer BF may be disposed on the substrate SUB. The buffer layer BF can prevent the permeation of air or moisture through the substrate SUB. The buffer layer BF may include multiple inorganic films stacked on one another alternately.

For example, the buffer layer BF may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The transistor TFT may be disposed on the buffer layer BF. The transistor TFT may be a driving transistor of the pixel PX. The transistor TFT may include a semiconductor material. For example, the transistor TFT may include polysilicon, amorphous silicon, oxide semiconductor, or other semiconductor materials.

The transistor TFT may include an active layer ACT and a gate electrode GE. The active layer ACT may include a channel region CH overlapping with the gate electrode GE in the third direction DR3, and a source region SA and a drain region DRA located on the both sides of the channel region CH, respectively. During the process of fabricating the display device 10, the source region SA and the drain region DRA may become conductive by doping or another method, in which the source region SA and the drain region DRA have higher conductivity than the channel region CH.

The first insulating layer GI may be disposed over the active layer ACT. The first insulating layer GI can prevent permeation of air or moisture. For example, the first insulating layer GI may include a plurality of inorganic films stacked on one another alternately.

The first insulating layer GI may include an inorganic insulating material. Accordingly, the first insulating layer GI can electrically insulate the gate electrode GE from the active layer ACT.

For example, the first insulating layer GI may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The gate electrode GE may be disposed on the first insulating layer GI. The gate electrode GE may overlap with the channel region CH, with the first insulating layer GI between the gate electrode GE and the channel region CH in the third direction DR3.

The gate electrode GE may include a conductive material. For example, the gate electrode GE may include at least one of molybdenum (Mo), aluminum (Al), chromium (Cr), gold (Au), silver (Ag), titanium (Ti), nickel (Ni), neodymium (Nd), copper (Cu) and other metals, alloys thereof, or other conductive materials.

The first conductive layer CP1 may be disposed on the first insulating layer GI. The first conductive layer CP1 may be electrically connected to the active layer ACT of the transistor TFT through a first contact hole CNTH1 penetrating the first insulating layer GI.

The first conductive layer CP1 may include a (1-1) conductive pattern CP11 and a (1-2) conductive pattern CP12. The (1-1) conductive pattern CP11 may be connected to the drain region DRA of the transistor TFT through a first contact hole CNTH1, and the (1-2) conductive pattern CP12 may be connected to the source region SA of the transistor TFT through a first contact hole CNTH1. For example, the (1-1) conductive pattern CP11 may be a drain electrode, and the (1-2) conductive pattern CP12 may be a source electrode.

The first conductive layer CP1 may include a conductive material. For example, the first connection metal layer M11 may include at least one of molybdenum (Mo), aluminum (Al), chromium (Cr), gold (Au), silver (Ag), titanium (Ti), nickel (Ni), neodymium (Nd), copper (Cu) and other metals, alloys thereof, or other conductive materials.

The structure of the first conductive layer CP1 will be described in detail later.

The second insulating layer ILD may be located over the gate electrode GE and the first conductive layer CP1. The second insulating layer ILD can prevent the penetration of air or moisture from the outside. The second insulating layer ILD may include a plurality of inorganic films that are stacked on one another alternately.

For example, the second insulating layer ILD may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The second conductive layer CP2 may be disposed on the second insulating layer ILD. The second conductive layer CP2 may be connected to the first conductive layer CP1 through a second contact hole CNTH2 penetrating the second insulating layer ILD. For example, the second conductive layer CP2 may include at least one of a variety of lines disposed in the display area DDA of FIG. 6.

The second conductive layer CP2 may include a (2-1) conductive pattern CP21 and a (2-2) conductive pattern CP22. The (2-1) conductive pattern CP21 may be connected to the (1-1) conductive pattern CP11, and the (2-2) conductive pattern CP22 may be connected to the (1-2) conductive pattern CP12.

The second conductive layer CP2 may include a conductive material. For example, the second conductive layer CP2 may include at least one of molybdenum (Mo), aluminum (Al), chromium (Cr), gold (Au), silver (Ag), titanium (Ti), nickel (Ni), neodymium (Nd), copper (Cu) and other metals, alloys thereof, or other conductive materials.

The structure of the second conductive layer CP2 will be described in detail later.

The first via layer VIA1 may be disposed on the second insulating layer ILD and may cover the second conductive layer CP2. The first via layer VIA1 may provide a flat surface over the underlying structures.

The first via layer VIA1 may include an organic material. For example, the first via layer VIA1 may include an acryl resin, an epoxy resin, a phenolic resin, a polyamide resin, a polyimide resin, or the like.

The third conductive layer CP3 may be disposed on the first via layer VIA1. The third conductive layer CP3 may be electrically connected to the second conductive layer CP2 through a third contact hole CNTH3 penetrating the first via layer VIA1. For example, the third conductive layer CP3 may be a connecting electrode that electrically connects the second conductive layer CP2 with the anode electrode AE.

The structure of the third conductive layer CP3 will be described in detail later.

The second via layer VIA2 may be disposed on the first via layer VIA1 and may cover the third conductive layer CP3. The second via layer VIA2 may provide a flat surface over the underlying structures.

The second via layer VIA2 may include an organic material. For example, the second via layer VIA2 may include an acryl resin, an epoxy resin, a phenolic resin, a polyamide resin, a polyimide resin, or the like.

The display element layer EML may be disposed on the transistor layer TFTL. The display element layer EML may include a light-emitting element ED and a pixel-defining layer PDL. The light-emitting element ED may include the anode electrode AE, an emissive layer EL, and a common electrode CE.

The anode electrode AE of the light-emitting element ED may be disposed on the second via layer VIA2. The anode electrode AE may be connected to the third conductive layer CP3 through an anode contact hole ACTH penetrating through the second via layer VIA2.

The anode electrode AE may be made up of a single layer of silver (Ag), molybdenum (Mo), titanium (Ti), copper (Cu) or aluminum (Al), or may be made up of a stack structure of aluminum and titanium (Ti/Al/Ti), a stack structure of aluminum and ITO (ITO/Al/ITO), an APC alloy and a stack structure of an APC alloy and ITO (ITO/APC/ITO) in order to increase the reflectivity. The APC alloy may be an alloy of silver (Ag), palladium (Pd) and copper (Cu).

The pixel-defining layer PDL may be disposed on the second via layer VIA2. The pixel-defining layer PDL defines a pixel opening SOP and may expose the anode electrode AE in the pixel opening SOP. The pixel-defining layer PDL may cover the edges of the anode electrode AE.

The pixel-defining layer PDL may include an organic material or an inorganic material.

In an example in which the pixel-defining layer PDL includes an organic material, the pixel-defining layer PDL may include an acryl resin, an epoxy resin, a phenolic resin, a polyamide resin and a polyimide resin, or the like.

In an example in which the pixel-defining layer PDL includes an inorganic material, the pixel-defining layer PDL may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The emissive layer EL of the light-emitting element ED may be located on the anode electrode AE. The emissive layer EL may include an organic material to emit light of a certain color. For example, the emissive layer EL may include a hole transporting layer, an organic material layer, and an electron transporting layer. The organic material layer may include a host and a dopant. The organic material layer may include a material that emits a predetermined light, and may be formed using a phosphor or a fluorescent material.

The cathode electrode CE of the light-emitting element ED may be located on the emissive layer EL. The cathode electrode CE may be located to cover the emissive layer EL. The cathode electrode CE may be a common layer disposed across a plurality of emissive layers EL.

The cathode electrode CE may be formed of a transparent conductive material (TCP) such as, for example, ITO and IZO that can transmit light, or a semi-transmissive conductive material such as, for example, magnesium (Mg), silver (Ag) and an alloy of magnesium (Mg) and silver (Ag). In an example in which the cathode electrode CE is formed of a semi-transmissive metal material, the light extraction efficiency can be increased by using microcavities.

The thin-film encapsulation layer TFEL may be formed on the display element layer EML. The thin-film encapsulation layer TFEL may include at least one inorganic film to prevent permeation of oxygen or moisture into the display element layer EML. The thin-film encapsulation layer TFEL may include at least one organic film to protect the display element layer EML from particles such as, for example, dust.

The thin-film encapsulation layer TFEL may include a first encapsulation layer TFE1, a second encapsulation layer TFE2 and a third encapsulation layer TFE3.

The first encapsulation layer TFE1 may be located on the cathode electrode CE and may entirely cover the cathode electrode CE.

The first encapsulation layer TFE1 may include an inorganic insulating material. For example, the first encapsulation layer TFE1 may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The second encapsulation layer TFE2 may be located on the first encapsulation layer TFE1 and may entirely cover the first encapsulation layer TFE1. The second encapsulation layer TFE2 may provide a flat surface over the first encapsulation layer TFE1.

The second encapsulation layer TFE2 may include an organic material, and may be, for example, an organic film such as, for example, an acrylic resin, an epoxy resin, a silicone resin, a silicone-acryl resin, a phenolic resin, a polyamide resin, and a polyimide resin.

The third encapsulation layer TFE3 may be located on the second encapsulation layer TFE2 and may entirely cover the second encapsulation layer TFE2.

The third encapsulation layer TFE3 may include an inorganic insulating material. For example, the first encapsulation layer TFE1 may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

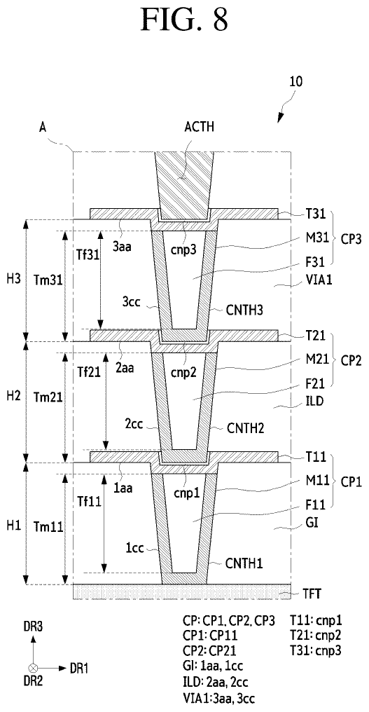

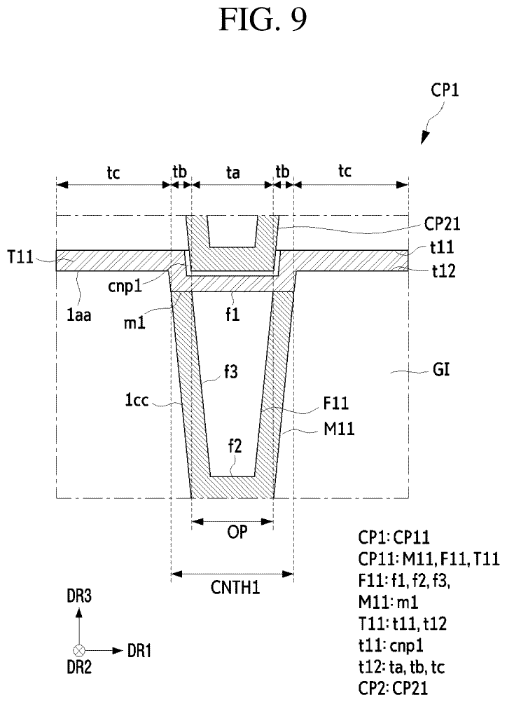

FIG. 8 is an enlarged cross-sectional view of area A of FIG. 7. FIG. 9 is an enlarged cross-sectional view of the first conductive layer of FIG. 8.

Referring to FIGS. 8 and 9 in conjunction with FIGS. 1 to 7, the (1-1) conductive pattern CP11 included in the first conductive layer CP1 may include a first connection metal layer M11, a first filling layer F11, and a first metal layer T11. In the following descriptions, the (1-1) conductive pattern CP11 will be described as the first conductive layer CP1.

According to one or more embodiments, the first filling layer F11 may be located in a first contact hole CNTH1. The first filling layer F11 may be located inside the first contact hole CNTH1. In the cross-sectional view, the first filling layer F11 may be entirely surrounded by the first connection metal layer M11 and the first metal layer T11.

The first filling layer F11 may provide a flat surface by filling the first connection metal layer M11 (i.e., filling in valleys of the first connection metal layer M11). The flat surface provided by the first filling layer F11 may assist in the first metal layer T11 having the minimum or optimal height difference (i.e., with respect to the height H1 of the first contact hole CNTH1).

In some embodiments, the thickness Tf11 of the first filling layer F11 may be less than the height H1 of the first contact hole CNTH1. For example, the thickness Tf11 of the first filling layer F11 may have a value that ranges from 70% to less than 100% of the height H1 of the first contact hole CNTH1.

In other words, the first filling layer F11 may be located inside the first contact hole CNTH1 and may have the thickness Tf11 less than the height H1 of the first contact hole CNTH1. The thickness Tf11 of the first filling layer F11 may have a value that ranges from 70% to less than 100% of the height H1 of the first contact hole CNTH1.

For example, if the thickness Tf11 of the first filling layer F11 has a value less than 70%, the first filling layer F11 cannot provide a sufficiently flat surface over the first connection metal layer M11. As a result, a contact failure may occur on the first metal layer T11 located on the first filling layer F11.

In some aspects, if the thickness Tf11 of the first filling layer F11 has a value equal to or greater than 100%, the first filling layer F11 may have a convex shape on one side in the third direction DR3, and thus contact failure between other conductive layers may occur.

The first filling layer F11 may include an organic material or an inorganic material.

For example, if the first filling layer F11 includes an organic material, the first filling layer F11 may include an acryl resin, an epoxy resin, a phenolic resin, a polyamide resin, a polyimide resin, or the like.

For example, if the first filling layer F11 includes an inorganic material, the first filling layer F11 may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

In some embodiments, the first filling layer F11 may include a first surface f1, a second surface f2, and a side surface f3. The first surface f1 may face the first metal layer T11, the second surface f2 may be opposite to the first surface f1, and the side surface f3 may connect the first surface f1 with the second surface f2.

According to embodiments of the present disclosure, the first filling layer F11 may be formed by an etch-back process in the process of fabricating the display device 10. Such a fabrication process will be described later.

According to one or more embodiments, the first connection metal layer M11 may be located in the first contact hole CNTH1. In the first contact hole CNTH1, the first connection metal layer M11 may be used to fill between the first insulating layer GI and the first filling layer F11.

The first connection metal layer M11 may assist in connecting the first metal layer T11 with a conductive material (e.g., the transistor TFT).

The first connection metal layer M11 may include a conductive material. For example, the first connection metal layer M11 may include at least one of molybdenum (Mo), aluminum (Al), chromium (Cr), gold (Au), silver (Ag), titanium (Ti), nickel (Ni), neodymium (Nd), copper (Cu) and other metals, alloys thereof, or other conductive materials.

The first insulating layer GI may include a side surface 1cc and a first surface 1aa. The side surface 1cc may face the first contact hole CNTH1, and the first surface 1aa may face the second insulating layer ILD.

According to embodiments of the present disclosure, the first connection metal layer M11 may be in contact with the side surface 1cc of the first insulating layer GI, but may not be in contact with the first surface 1aa of the first insulating layer GI. This may mean that the first connection metal layer M11 is located inside the first contact hole CNTH1.

The first connection metal layer M11 may be in contact with the second surface f2 and the side surface f3 of the first filling layer F11. The first connection metal layer M11 may completely cover the second surface f2 and the side surface f3 of the first filling layer F11.

In some embodiments, the first connection metal layer M11 may include a first surface m1 facing the first metal layer T11. The first surface m1 of the first connection metal layer M11 may define an opening OP located in the first contact hole CNTH1. The first surface m1 of the first connection metal layer M11 may surround the opening OP.

The first connection metal layer M11 may expose the first filling layer F11 in the opening OP. Accordingly, the first surface f1 of the first filling layer F11 may be exposed without being covered by the first connection metal layer M11.

In some embodiments, the thickness Tm11 of the first connection metal layer M11 may be less than the height H1 of the first contact hole CNTH1. For example, the thickness Tm11 of the first connection metal layer M11 may have a value that ranges from 70% to less than 100% of the height H1 of the first contact hole CNTH1.

In other words, the first connection metal layer M11 may be located inside the first contact hole CNTH1 and may have the thickness Tm11 less than the height H1 of the first contact hole CNTH1. The thickness Tm11 of the first connection metal layer M11 may have a value that ranges from 70% to less than 100% of the height H1 of the first contact hole CNTH1.

For example, if the thickness Tm11 of the first connection metal layer M11 has a value less than 70% or greater than 100%, a contact failure may occur between the first connection metal layer M11 and the first metal layer T11.

According to one or more embodiments, the first connection metal layer M11 may be formed by an etch-back process in the process of fabricating the display device 10. Such a fabrication process will be described later.

According to embodiments of the present disclosure, the first metal layer T11 may be located such that the first metal layer T11 overlaps with the first contact hole CNTH1. The first metal layer T11 may be extended from the first contact hole CNTH1 and may also be located such that portions of the first metal layer T11 do not overlap with the first contact hole CNTH1.

The first metal layer T11 may include at least one of a variety of electrodes or lines disposed in the display area DDA of FIG. 6.

The first metal layer T11 may include a conductive material. For example, the first connection metal layer M11 may include at least one of molybdenum (Mo), aluminum (Al), chromium (Cr), gold (Au), silver (Ag), titanium (Ti), nickel (Ni), neodymium (Nd), copper (Cu) and other metals, alloys thereof, or other conductive materials.

The first metal layer T11 may be in contact with the first filling layer F11 and the first connection metal layer M11 in the first contact hole CNTH1. For example, the first metal layer T11 may be in contact with the first surface f1 of the first filling layer F11 and the first surface m1 of the first connection metal layer M11. In other words, the first filling layer F11 and the first connection metal layer M11 may be in contact with and electrically connected with each other in the first contact hole CNTH1.

The first metal layer T11 may be in contact with the first surface 1aa and the side surface 1cc of the first insulating layer GI.

According to embodiments of the present disclosure, the first metal layer T11 may have a height difference (i.e., a change in height) at the first contact hole CNTH1. The height difference of the first metal layer T11 may be less than 30% of the height H1 of the first contact hole CNTH1. In other words, since the first metal layer T11 according to the embodiment includes the first filling layer F11 thereunder, the first metal layer T11 may have a height difference less than 30% of the height H1 of the first contact hole CNTH1. Therefore, the first metal layer T11 according to embodiments of the present disclosure may be formed without a contact failure caused by the height difference.

According to embodiments of the present disclosure, the first metal layer T11 may include a first surface t11 and a second surface t12. The first surface t11 may face one side in the third direction DR3, and the second surface t12 may be opposite to the first surface t11.

According to embodiments of the present disclosure, the second surface t12 may include a first portion ta, a second portion tb and a third portion tc, which are in contact with the different layers, respectively. The first portion ta may be in contact with the first filling layer F11, the second portion tb may be in contact with the first connection metal layer M11, and the third portion tc may be in contact with the first insulating layer GI.

The first metal layer T11 may be electrically connected to the first connection metal layer M11 through the second portion tb. The second portion tb may be located between the first portion ta and the third portion tc.

According to embodiments of the present disclosure, the first surface t11 of the first metal layer T11 may be in contact with the (2-1) conductive pattern CP21 included in the second conductive layer CP2. A part of the first surface t11 where the first metal layer T11 and the second conductive layer CP2 come into contact with each other may be referred to as a first connecting portion cnp1. The first conductive layer CP1 and the second conductive layer CP2 may be electrically connected with each other through the first connecting portion cnp1.

According to one or more embodiments, the first connecting portion cnp1 may be located such that the first connecting portion cnp1 overlaps with the first contact hole CNTH1 in the third direction DR3.

According to one or more embodiments, the (2-1) conductive pattern CP21 included in the second conductive layer CP2 may be in contact with the (1-1) conductive pattern CP11 included in the first conductive layer CP1. The (1-1) conductive pattern CP11 and the (2-1) conductive pattern CP21 may have a structure in which they are stacked in the third direction DR3. In other words, the first conductive layer CP1 and the second conductive layer CP2 may be located on the same line in the third direction DR3.

In other words, the first contact hole CNTH1 and the second contact hole CNTH2 may overlap each other in the third direction DR3, and the first contact hole CNTH1 and the second contact hole CNTH2 may be located on the same line in the third direction DR3.

The (2-1) conductive pattern CP21 included in the second conductive layer CP2 may include a second connection metal layer M21, a second filling layer F21 and a second metal layer T21. In the following descriptions, the (2-1) conductive pattern CP21 will be described as the second conductive layer CP2.

According to one or more embodiments, the second filling layer F21 may be located in the second contact hole CNTH2. The second filling layer F21 may be located inside the second contact hole CNTH2. In the cross-sectional view, the second filling layer F21 may be entirely surrounded by the second connection metal layer M21 and the second metal layer T21.

The second filling layer F21 may provide a flat surface by filling the second connection metal layer M21. The flat surface provided by the second filling layer F21 may assist the second metal layer T21 in having the minimum or optimal height difference.

In some embodiments, the thickness Tf21 of the second filling layer F21 may be less than the height H2 of the second contact hole CNTH2. For example, the thickness Tf21 of the second filling layer F21 may have a value that ranges from 70% to less than 100% of the height H2 of the second contact hole CNTH2. Redundant descriptions thereof will be omitted.

The second filling layer F21 may include the same material as the first filling layer F11. For example, the second filling layer F21 may include an organic material or an inorganic material. Redundant descriptions thereof will be omitted.

According to embodiments of the present disclosure, the second filling layer F21 may be formed by an etch-back process in the process of fabricating the display device 10.

According to one or more embodiments, the second connection metal layer M21 may be located in the second contact hole CNTH2. In the second contact hole CNTH2, the second connection metal layer M21 may be used to fill between the second insulating layer ILD and the second filling layer F21.

The second connection metal layer M21 may assist in connecting the second metal layer T21 with a conductive material (e.g., the first conductive layer CP1).

The second connection metal layer M21 may include a conductive material and may include the same material as the first connection metal layer M11. Redundant descriptions thereof will be omitted.

The second insulating layer ILD may include a side surface 2cc and a first surface 2aa. The side surface 2cc may face the second contact hole CNTH2, and the first surface 2aa may face the first via layer VIA1.

According to embodiments of the present disclosure, the second connection metal layer M21 may be in contact with the side surface 2cc of the second insulating layer ILD, but may not be in contact with the first surface 2aa of the second insulating layer ILD. This may mean that the second connection metal layer M21 is located inside the second contact hole CNTH2.

The second connection metal layer M21 may completely cover the lower surface and side surface of the second filling layer F21 and expose a part of the upper surface of the second filling layer F21.

In some embodiments, the thickness Tm21 of the second connection metal layer M21 may be less than the height H2 of the second contact hole CNTH2. For example, the thickness Tm21 of the second connection metal layer M21 may have a value that ranges from 70% to less than 100% of the height H2 of the second contact hole CNTH2. Redundant descriptions thereof will be omitted.

According to one or more embodiments, the second connection metal layer M21 may be formed by an etch-back process in the process of fabricating the display device 10.

According to one or more embodiments, the second metal layer T21 may be located in the second contact hole CNTH2. The second metal layer T21 may be extended from the second contact hole CNTH2 and may be located outside the second contact hole CNTH2.

The second metal layer T21 may include at least one of a variety of electrodes or lines disposed in the display area DDA of FIG. 6.

The second metal layer T21 may include a conductive material and may include the same material as the first metal layer T11. Redundant descriptions thereof will be omitted.

The second metal layer T21 may be in contact with the second filling layer F21 and the second connection metal layer M21 in the second contact hole CNTH2. In other words, the second filling layer F21 and the second connection metal layer M21 may be in contact with and electrically connected with each other in the second contact hole CNTH2.

According to embodiments of the present disclosure, the second metal layer T21 may have a height difference at the second contact hole CNTH2. The height difference of the second metal layer T21 may be less than 30% of the height H2 of the second contact hole CNTH2. In other words, since the second metal layer T21 according to the embodiment includes the second filling layer F21 thereunder, the second metal layer T21 may have a height difference less than 30% of the height H2 of the second contact hole CNTH2. Therefore, the second metal layer T21 according to embodiments of the present disclosure may be formed without a contact failure caused by the height difference.

According to embodiments of the present disclosure, the second metal layer T21 may be in contact with the third conductive layer CP3. The second conductive layer CP2 and the third conductive layer CP3 may be electrically connected through the second connecting portion cnp2. The second connecting portion cnp2 may be located such that the second connecting portion cnp2 overlaps with the second contact hole CNTH2 in the third direction DR3.

According to an embodiment, the second insulating layer ILD may have a structure in which multiple inorganic insulating layers are stacked on one another, and multiple second conductive layers CP2 may be located between the inorganic insulating layers. That is to say, according to an embodiment, multiple second conductive layers CP2 and multiple second insulating layers ILD may be alternately stacked on one another.

According to embodiments of the present disclosure, the third conductive layer CP3 may be in contact with the (2-1) conductive pattern CP21 included in the second conductive layer CP2. The third conductive layer CP3 and the (2-1) conductive pattern CP21 may have a structure in which they are stacked in the third direction DR3. In other words, the second conductive layer CP2 and the third conductive layer CP3 may be located on the same line in the third direction DR3.

In other words, the second contact hole CNTH2 and the third contact hole CNTH3 may overlap each other in the third direction DR3, and the second contact hole CNTH2 and the third contact hole CNTH3 may be located on the same line in the third direction DR3.

The third conductive layer CP3 may include a third connection metal layer M31, a third filling layer F31, and a third metal layer T31.

According to embodiments of the present disclosure, the third filling layer F31 may be located in a third contact hole CNTH3. The third filling layer F31 may be located inside the third contact hole CNTH3. In the cross-sectional view, the third filling layer F31 may be entirely surrounded by the third connection metal layer M31 and the third metal layer T31.

The third filling layer F31 may provide a flat surface by filling the third connection metal layer M31. The flat surface provided by the third filling layer F31 may assist the third metal layer T31 in having the minimum or optimal height difference.

In some embodiments, the thickness Tf31 of the third filling layer F31 may be less than the height H3 of the third contact hole CNTH3. For example, the thickness Tf31 of the third filling layer F31 may have a value that ranges from 70% to less than 100% of the height H3 of the third contact hole CNTH3. Redundant descriptions thereof will be omitted.

The third filling layer F31 may include the same material as the first filling layer F11. For example, the third filling layer F31 may include an organic material or an inorganic material. Redundant descriptions thereof will be omitted.

According to embodiments of the present disclosure, the third filling layer F31 may be formed by an etch-back process in the process of fabricating the display device 10.

According to one or more embodiments, the third connection metal layer M31 may be located in the third contact hole CNTH3. In the third contact hole CNTH3, the third connection metal layer M31 may be used to fill between the first via layer VIA1 and the third filling layer F31.

The third connection metal layer M31 may assist in connecting the third metal layer T31 with a conductive material (e.g., the second conductive layer CP1).

The third connection metal layer M31 may include a conductive material and may include the same material as the first connection metal layer M11. Redundant descriptions thereof will be omitted.

The first via layer VIA1 may include a side surface 3cc and a first surface 3aa. The side surface 3cc may face the third contact hole CNTH3, and the first surface 3aa may face the anode electrode AE.

According to embodiments of the present disclosure, the third connection metal layer M31 may be in contact with the side surface 3cc of the first via layer VIA1, but may not be in contact with the first surface 3aa of the first via layer VIA1. This may mean that the third connection metal layer M31 is located inside the third contact hole CNTH3.

The third connection metal layer M31 may completely cover the lower surface and side surface of the third filling layer F31 and expose a part of the upper surface of the third filling layer F31.

In some embodiments, the thickness Tm31 of the third connection metal layer M31 may be less than the height H3 of the third contact hole CNTH3. For example, the thickness Tm31 of the third connection metal layer M31 may have a value that ranges from 70% to less than 100% of the height H3 of the third contact hole CNTH3. Redundant descriptions thereof will be omitted.

According to one or more embodiments, the third connection metal layer M13 may be formed by an etch-back process in the process of fabricating the display device 10.

According to one or more embodiments, the third metal layer T31 may be located in the third contact hole CNTH3. The third metal layer T31 may be extended from the third contact hole CNTH3 and may also be located such that portions of the third metal layer T31 do not overlap with the third contact hole CNTH3.

The third metal layer T31 may include at least one of a variety of electrodes or lines disposed in the display area DDA of FIG. 6.

The third metal layer T31 may include a conductive material and may include the same material as the first metal layer T11. Redundant descriptions thereof will be omitted.

The third metal layer T31 may be in contact with the third filling layer F31 and the third connection metal layer M31 in the third contact hole CNTH3. In other words, the third metal layer T31 may be electrically connected to the third connection metal layer M31 in the third contact hole CNTH3.

According to embodiments of the present disclosure, the third metal layer T31 may have a height difference at the third contact hole CNTH3. The height difference of the third metal layer T31 may be less than 30% of the height H3 of the third contact hole CNTH3. In other words, since the third metal layer T31 according to the embodiment includes the third filling layer F31 that provides a flat surface by filling the third connection metal layer M31, the third metal layer T31 may have a height difference less than 30% of the height H3 of the third contact hole CNTH3. Therefore, the third metal layer T31 according to embodiments of the present disclosure may be formed without a contact failure caused by the height difference.

According to embodiments of the present disclosure, the third metal layer T31 may be in contact with the anode electrode AE through the anode contact hole ACTH. The anode contact hole ACTH may be filled with the anode electrode AE.

The second conductive layer CP2 and the anode electrode AE may be electrically connected through a third connecting portion cnp3. The third connecting portion cnp3 may be located such that the third connecting portion cnp3 overlaps with the third contact hole CNTH3 in the third direction DR3.

Typically, in a display device applied to a high-resolution device, a plurality of conductive layers may be formed in a narrow area. Accordingly, in a high-resolution display device, it may be a major factor that multiple conductive layers are arranged to have a minimum area or width. In some aspects, in such a high-resolution display device, it may be a major factor that the multiple conductive layers are in stable contact with each other in addition to having the minimum area or width.

In the display device 10 according to embodiments of the present disclosure, the multiple conductive layers, i.e., the first conductive layer CP1, the second conductive layer CP2, and the third conductive layer CP3 are stacked on one another in the third direction DR3, such that they can be arranged within the minimum area.

By doing so, in the display device 10 according to embodiments of the present disclosure, the first to third connecting portions cnp1, cnp2 and cnp3 of the first conductive layer CP1, the second conductive layer CP2 and the third conductive layer CP3, respectively, with the anode electrode AE can located on the same line and/or in a row in the third direction DR3.

In other words, the first contact hole CNTH1, the second contact hole CNTH2, the third contact hole CNTH3, and the anode contact hole ACTH included in the display device 10 according to embodiments of the present disclosure may be located on the same line and/or in a row in the third direction DR3.

In some aspects, as the display device 10 according to embodiments of the present disclosure includes the filling layer that can provide a flat surface over the metal layer, and further, the connection metal layer having conductivity, the multiple conductive layers can make electrically stable contact.

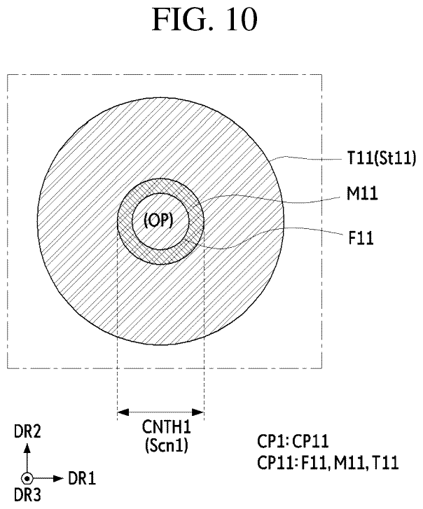

FIG. 10 is an enlarged plan view of the first conductive layer of FIG. 8.

Referring to FIG. 10 in conjunction with FIGS. 7 to 9, the first connection metal layer M11 and the first filling layer F11 of the first conductive layer CP1 may be located in the first contact hole CNTH1 when viewed from above.

When viewed from above, the first connection metal layer M11 may define an opening OP and may expose the first filling layer F11 in the opening OP. In other words, the first connection metal layer M11 may completely surround the first filling layer F11 when viewed from above.

When viewed from above, the first metal layer T11 of the first conductive layer CP1 may be located in the first contact hole CNTH1 and may extend outward from the inside of the first contact hole CNTH1 such that portions the first metal layer T11 are located outside the first contact hole CNTH1.

In other words, the area St11 of the first metal layer T11 may be larger than the area Scn1 of the first contact hole CNTH1 when viewed from above.

When viewed from above, the first metal layer T11 may be generally in contact with and cover the first connection metal layer M11 and the first metal layer F11. Accordingly, the first metal layer T11 may be electrically connected to the first connection metal layer M11.

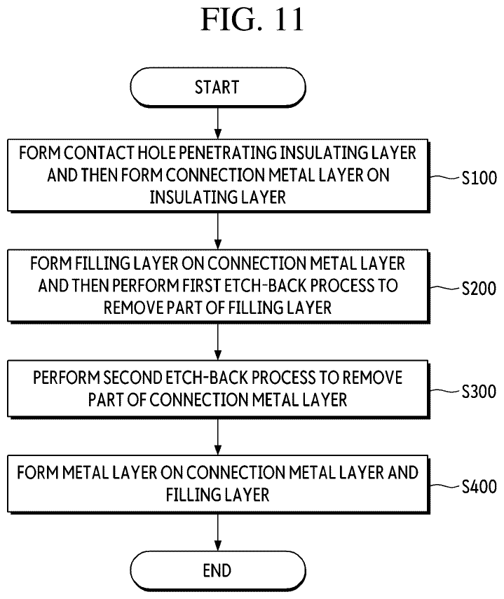

FIG. 11 is a flowchart for illustrating a method for fabricating the first conductive layer in FIG. 7.

In the descriptions of the methods and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 11, a method for fabricating a display device 10 (step S1) according to an embodiment may include: forming a contact hole penetrating an insulating layer and then forming a connection metal layer on the insulating layer (step S100); forming a filling layer on the connection metal layer and then performing a first etch-back process which removes a part of the filling layer (step S200); performing a second etch-back process which removes a part of the connection metal layer (step S300); and forming a metal layer on the connection metal layer and the filling layer (step S400).

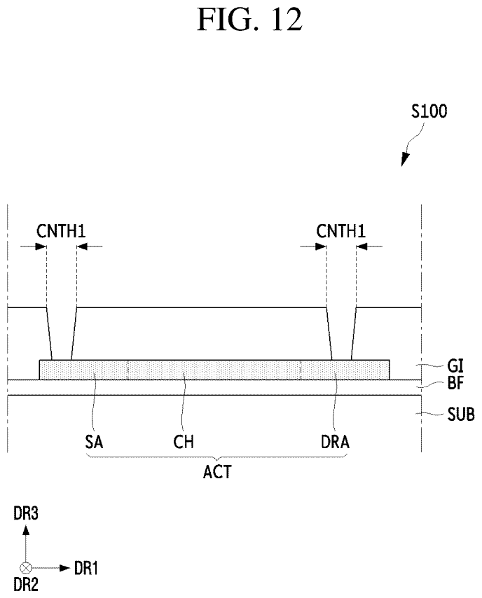

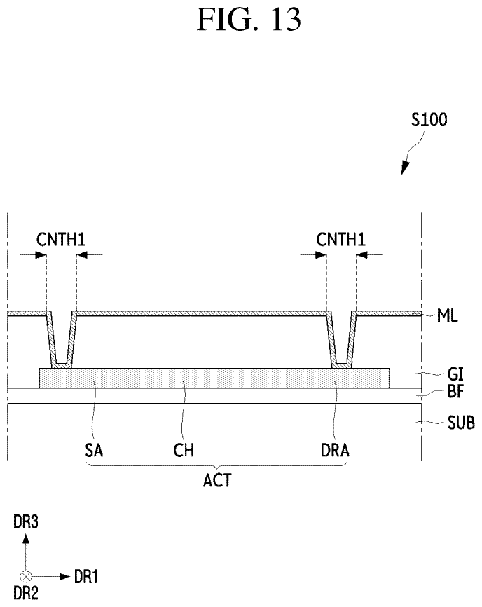

FIGS. 12 and 13 are cross-sectional views illustrating step S100 of FIG. 11.

Referring to FIGS. 12 and 13, step S100 of forming the contact hole penetrating the insulating layer and then forming the connection metal layer on the insulating layer will be described.

Initially, the method may include forming a buffer layer BF on a substrate SUB, forming an active layer ACT on the buffer layer BF, and then forming a first insulating layer GI covering the active layer ACT. The active layer ACT may include a channel region CH, a source region SA, and a drain region DRA. The source region SA and the drain region DRA may be located on the both sides of the channel region CH, respectively.

Subsequently, the method may include forming a first contact hole CNTH1 which exposes each of the source region SA and the drain region DRA. In this process, the first contact hole CNTH1 may be formed via an etching process (e.g., a dry etching process) using a mask pattern.

For example, the dry etching process may be conducted via a reactive ion etching (RIE) process using a reactive gas such as, for example, CHF₃, CH₃F, CH₂F₂, CHF₆, CF₄, C2F₆ and C₃F₆, and sputtering gas such as, for example, Ar and O₂/Ar. In this instance, an inductively coupled plasma (ICP) source or a capacitively coupled plasma (CCP) source may be used as the plasma source.

In this process, a part of the source region SA and a part of the drain region DRA of the active layer ACT may be exposed in the first contact holes CNTH1.

Subsequently, the method may include forming a connection metal layer ML on the first insulating layer GI.

In this process, the connection metal layer ML may be formed via a deposition process using at least one of the above-listed conductive metal materials. The material and/or method for forming the connection metal layer ML may vary depending on embodiments.

In this process, the connection metal layer ML may entirely cover the first insulating layer GI. The connection metal layer ML can cover a part of the source region SA and a part of the drain region DRA of the active layer ACT in the first contact holes CNTH1.

The connection metal layer ML may cover the height differences of the first insulating layer GI with a uniform thickness. Accordingly, the connection metal layer ML may have height differences in the first contact holes CNTH1.

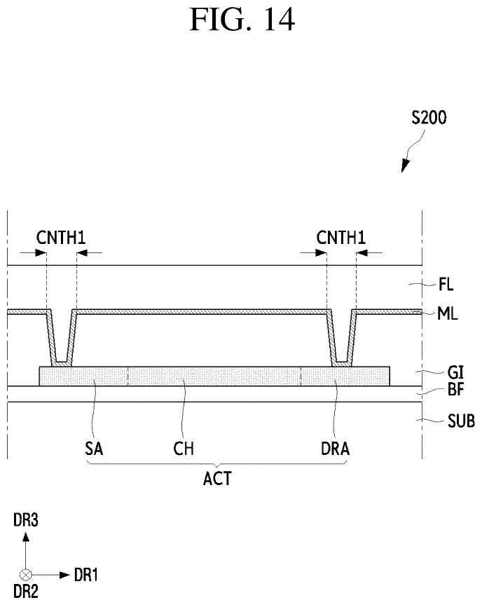

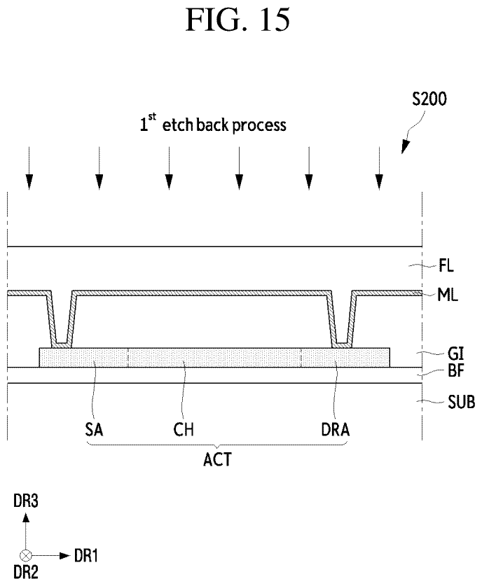

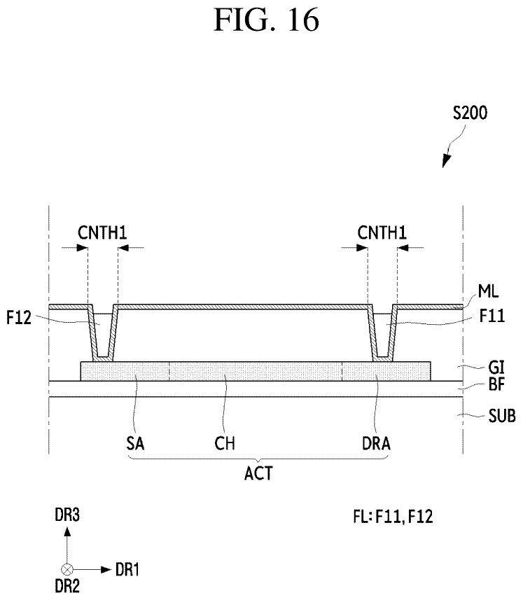

FIGS. 14 to 16 are cross-sectional views illustrating step S200 of FIG. 11.

Referring to FIGS. 14 to 16, step S200 of forming the filling layer on the connection metal layer and then performing the first etch-back process which removes a part of the filling layer (step S200) will be described.

Initially, the method may include forming the filling layer FL on the connection metal layer ML. The filling layer FL may be formed entirely on the connection metal layer ML.

For example, the filling layer FL may be formed via a coating process using at least one of the above-listed organic materials, or may be formed via a process of forming an insulating film using at least one of the above-listed insulating material (e.g., an inorganic insulating material). The material and/or method for forming the filling layer FL may vary depending on embodiments.

In this process, the filling layer FL may be used to fill the height difference formed by the connection metal layer ML in the first contact hole CNTH1.

Subsequently, the method may include performing the first etch-back process (1^{st} etch-back process). For example, the first etch back process may be performed for the purpose of planarizing the filling layer FL. The first etch-back process may be performed without any mask. The front surface of the filling layer FL may be partially etched (e.g., dry etching) by the first etch-back process. The method may include repeating the first etch-back process two or more times as required or as desired.

Through this process, the portions of the filling layer FL that do not overlap with the first contact hole CNTH1 may be completely removed, and the portions of the filling layer FL which overlap the first contact holes CNTH1 may remain. Thus, the filling layer FL may remain only in the first contact holes CNTH1.

In this process, the filling layer FL may include a first portion F11 overlapping with the drain region DRA and a second portion F12 overlapping with the source region SA. The first portion F11 and the second portion F12 may be spaced apart from each other in the first direction DR1, with the first insulating layer GI between the first portion F11 and the second portion F12. The first portion F11 may also be referred to as the first filling layer F11 herein.

In the display device 10 according to one or more embodiments, the filling layer FL inside the first contact hole CNTH1 can be formed without any mask, such that there are advantages of easier fabrication and reduced fabrication cost.

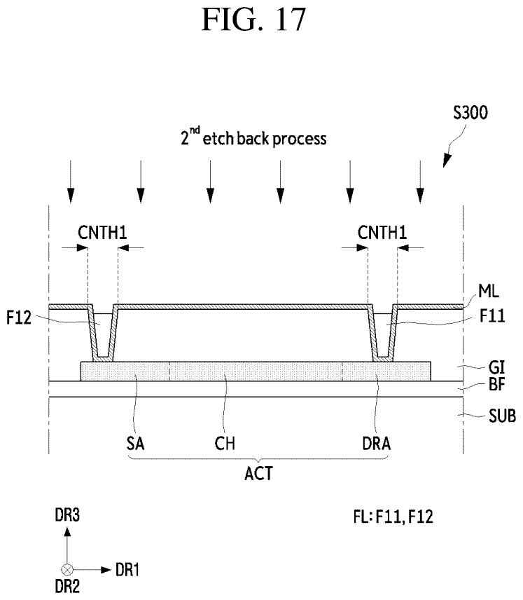

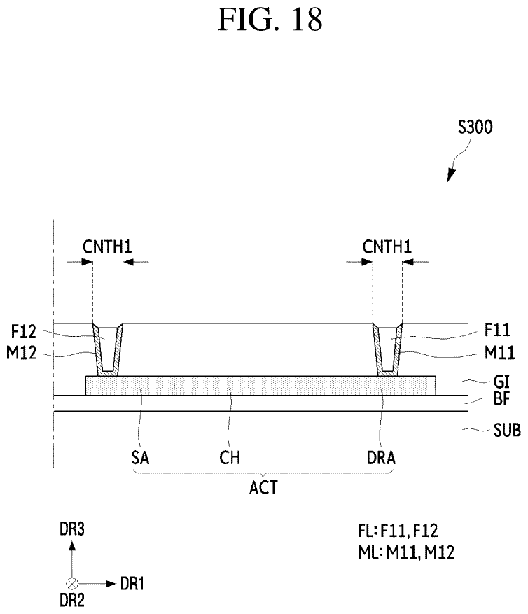

FIGS. 17 and 18 are cross-sectional views illustrating step S300 of FIG. 11.

Referring to FIGS. 17 and 18 in conjunction with FIGS. 1 to 16, step S300 of performing the second etch-back process which removes a part of the connection metal layer will be described.

Subsequently, the second etch-back process (2^{nd} etch-back process) is performed. For example, the second etch-back process may be performed for the purpose of removing a part of the connection metal layer ML. The second etch-back process may be performed without any mask. The front surface of the connection metal layer ML may be partially etched (e.g., dry etching). The method may include repeating the second etch-back process two or more times as required or as desired.

Through this process, portions of the connection metal layer ML that do not overlap with the first contact hole CNTH1 may be completely removed, and thus, the connection metal layer ML may remain only in the first contact holes CNTH1.

In some implementations, a surface treatment process may be further performed on the connection metal layer ML after the second etch-back process, such that the surface of the connection metal layer ML may be more exposed in the first contact hole CNTH1. It should be understood, however, that in some embodiments, the surface treatment process may not be essential but may be optional.

In some aspects, in some implementations, an etching process may be further performed on the filling layer FL after the second etch-back process, such that the surface of the connection metal layer ML may be more exposed in the first contact hole CNTH1. It should be understood, however, that the surface treatment process may not be essential but may be optional.

Referring to FIGS. 8 and 9, as described herein, in this process, the thickness of the connection metal layer ML and the thickness of the filling layer FL may be less than the height of the first contact hole CNTH1. Redundant descriptions thereof will be omitted.

In this process, the upper surface of the connection metal layer ML and the upper surface of the filling layer FL may be exposed.

In this process, the connection metal layer ML may include a first portion M11 overlapping with the drain region DRA and a second portion M12 overlapping with the source region SA. The first portion M11 and the second portion M12 may be spaced apart from each other in the first direction DR1, with the first insulating layer GI between the first portion M11 and the second portion M12. The first portion M11 may be referred to as a first connection metal layer M11 herein.

In the display device 10 according to one or more embodiments, the connection metal layer ML inside the first contact hole CNTH1 can be formed without any mask, such that there are advantages of easier fabrication and reduced fabrication cost.

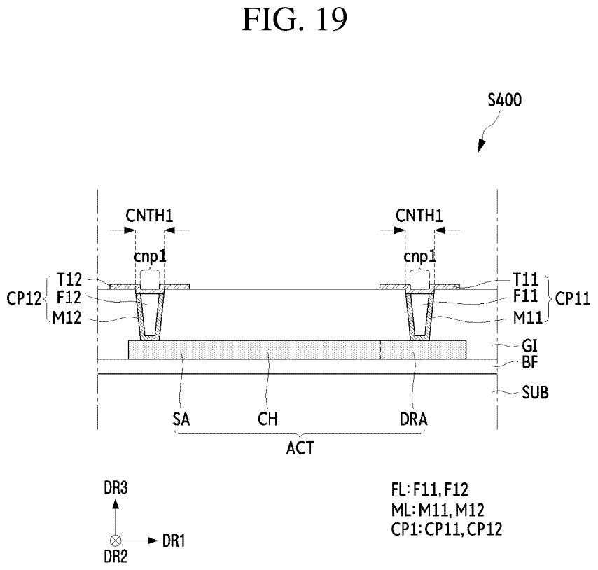

FIG. 19 is a cross-sectional view illustrating step S400 of FIG. 11.

Referring to FIG. 19, step S400 of forming a metal layer on the connection metal layer and the filling layer will be described.

Subsequently, a metal layer TL is formed on the connection metal layer ML and the filling layer FL located in the first contact hole CNTH1.

In this process, the metal layer TL may be formed via a process of forming a conductive film (e.g., a deposition process) and a patterning process of the conductive film (e.g., an etching process using a mask). The material and/or method for forming the metal layer TL may vary depending on embodiments. Accordingly, the metal layer TL may be formed as a pattern of conductive islands.

In this process, the metal layer TL may be in contact with and cover the connection metal layer ML and the filling layer FILM. Accordingly, the metal layer TL and the connection metal layer ML may be in contact with and electrically connected with each other in the first contact hole CNTH1.

The metal layer TL can be located on the relatively flat surface of the connection metal layer ML and the filling layer FL since the connection metal layer ML is filled with the filling layer FL. Redundant descriptions thereof will be omitted.

In this manner, the first conductive layer CP1 illustrated in FIG. 7 can be formed.

Referring to FIG. 19 in conjunction with FIGS. 7 to 9, a method for forming a second conductive layer CP2 may include forming a second insulating layer ILD on the first conductive layer CP1 and the first insulating layer GI, and then repeating the method S1 of fabricating the first conductive layer.

In the process described herein, the second contact hole CNTH2 may be formed on the same line as the first contact hole CNTH1 in the third direction DR3, and the second conductive layer CP2 may be formed to be in contact with the first connecting portion cnp1 of the first conductive layer CP1

In some aspects, a method for forming a third conductive layer CP3 may include forming a first via layer VIA1 on the second conductive layer CP2 and the second insulating layer ILD, and then repeating the method S1 of fabricating the first conductive layer.

In the process described herein, the third contact hole CNTH3 may be formed on the same line as the second contact hole CNTH2 in the third direction DR3, and the third conductive layer CP3 may be formed to be in contact with the second connecting portion cnp2 of the second conductive layer CP2.

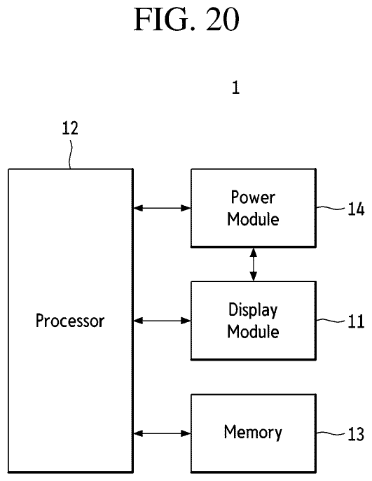

FIG. 20 is a block diagram of an electronic device according to an embodiment of the present disclosure.

Referring to FIG. 20 in conjunction with FIGS. 1 to 19, the display device 10 according to the embodiment may be applied to a variety of electronic devices 1. The electronic device 1 according to the embodiment may include the display device 10 described herein, and may further include a module or device having additional functions in addition to the display device 10.

The electronic device 1 according to the embodiment may include a display module 11, a processor 12, a memory 13, and a power module 14.

The processor 12 may include at least one of: a central processing unit (CPU), an application processor (AP), a graphic processing unit (GPU), a communication processor (CP), an image signal processor (ISP), and a controller.

The memory 13 may store data information supportive of the operation of the processor 12 or the display module 11. In an example in which the processor 12 executes an application stored in the memory 13, an image data signal and/or an input control signal may be transmitted to the display module 11. The display module 11 may process the received signal and output image information through a display screen.

The power module 14 may include a power supply module such as, for example, a power adapter and a battery device, and a power conversion module that converts the power supplied by the power supply module to generate power for the operation of the electronic device 1.

At least one of the elements of the electronic device 1 described herein may be included in the display devices according to the embodiments described herein. In some aspects, some of the individual modules functionally included in a single module may be included in a display device, and some others may be provided separately from the display device. For example, the display device may include the display module 11, and the processor 12, the memory 13 and the power module 14 may be implemented as other devices inside the electronic device 1 instead of the display device.

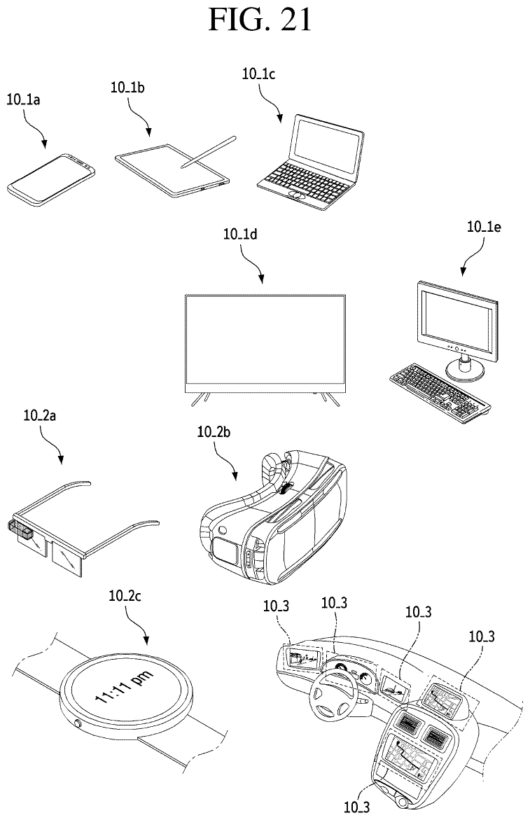

FIG. 21 is a view illustrating electronic devices according to a variety of embodiments of the present disclosure.

Referring to FIG. 21, a variety of electronic devices 1 employing the display devices 10 according to the embodiments may include not only image display electronic devices such as, for example, a smart phone 1_1a, a tablet PC 1_1b, a laptop computer 1_1c, a TV 1_1d and a desktop monitor 1_1e, but also wearable electronic devices including display modules such as, for example, smart glasses 1_2a, a head-mounted display 1_2b and a smart watch 1_2c, and electronic devices for vehicles 1_3 including display modules such as, for example, a center information display (CID) placed on the dashboard, the center fascia and the dashboard of a vehicle, and a room mirror display.

Embodiments of the disclosure should not be construed as being limited to the embodiments set forth herein. Rather, the example embodiments are provided such that this disclosure will be thorough and complete and will fully convey the concept of the invention to those skilled in the art.

While the invention has been particularly illustrated and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate comprising a conductive material;
a first insulating layer disposed on the substrate;
a first conductive layer connected to the conductive material through a first contact hole penetrating the first insulating layer;
a second insulating layer disposed on the first conductive layer; and
a second conductive layer connected to the first conductive layer through a second contact hole penetrating the second insulating layer,
wherein:
the first conductive layer comprises a first connection metal layer, a first filling layer; and a first metal layer in contact with and covering the first connection metal layer and the first filling layer,
the first connection metal layer and the first filling layer are located inside the first contact hole, and
a thickness of the first connection metal layer and a thickness of the first filling layer are less than a height of the first contact hole.

2. The display device of claim 1, wherein the thickness of the first connection metal layer and the thickness of the first filling layer have values that range from 70% to less than 100% of the height of the first contact hole.

3. The display device of claim 2, wherein:
the first insulating layer comprises a first surface facing the second insulating layer and a side surface facing the first contact hole, and
the first connection metal layer is in contact with the side surface of the first insulating layer but is not in contact with the first surface of the first insulating layer.

4. The display device of claim 3, wherein the first metal layer is in contact with the first surface and the side surface of the first insulating layer.

5. The display device of claim 4, wherein:
the first metal layer and the first connection metal layer are in contact with each other in the first contact hole, and
the first metal layer and the first connection metal layer are electrically connected with each other.

6. The display device of claim 1, wherein the first filling layer is entirely surrounded by the first metal layer and the first connection metal layer in a cross-section.

7. The display device of claim 1, wherein:
the second conductive layer is in contact with a first connecting portion of the first metal layer, and
the first connecting portion overlaps with the first contact hole and the second contact hole in a direction perpendicular to the substrate.

8. The display device of claim 7, wherein the second conductive layer comprises:
a second connection metal layer and a second filling layer located in the second contact hole; and
a second metal layer in contact with and covering the second connection metal layer and the second filling layer,
wherein the second connection metal layer is connected to the first metal layer through the first connecting portion.

9. The display device of claim 8, further comprising:
a via layer disposed on the second conductive layer; and
a third conductive layer connected to the second conductive layer through a third contact hole penetrating the via layer,
wherein:
the third conductive layer is in contact with a second connecting portion of the second metal layer, and
the first connecting portion and the second connecting portion overlap with each other in the direction perpendicular to the substrate.

10. The display device of claim 9, further comprising:
an anode electrode disposed on the via layer,
wherein the third conductive layer is in contact with the anode electrode through an anode contact hole.

11. The display device of claim 1, wherein:
the first connection metal layer defines an opening overlapping with the first contact hole when viewed from above, and
the first connection metal layer exposes the first filling layer in the opening when viewed from above.

12. The display device of claim 11, wherein the first connection metal layer completely surrounds the first filling layer when viewed from above.

13. The display device of claim 12, wherein the first connection metal layer and the first filling layer are located in the first contact hole when viewed from above.

14. A method for fabricating a display device, the method comprising:
forming a contact hole penetrating an insulating layer covering a substrate and then forming a connection metal layer on the insulating layer;
forming a filling layer on the connection metal layer and then performing a first etch-back process which removes a part of the filling layer;
performing a second etch-back process which removes a part of the connection metal layer; and
forming a metal layer on the connection metal layer and the filling layer.

15. The method of claim 14, wherein portions of the filling layer that do not overlap with the contact hole are completely removed via the first etch-back process without any mask.

16. The method of claim 14, wherein portions the connection metal layer that do not overlap with the contact hole are completely removed via the second etch-back process without any mask.

17. The method of claim 16, wherein:
a thickness of the connection metal layer and a thickness of the filling layer have values ranging from 70% to less than 100% of a height of the contact hole, and
the metal layer entirely covers the connection metal layer and the filling layer.

18. An electronic device comprising:
at least one display device comprising a substrate comprising a conductive material;
a display device housing in which the at least one display device is accommodated; and
an optical member which magnifies displayed images of the at least one display device or converts a light path of the displayed images,
wherein the at least one display device comprises:
a first insulating layer disposed on the substrate;
a first conductive layer connected to the conductive material through a first contact hole penetrating the first insulating layer;
a second insulating layer disposed on the first conductive layer; and
a second conductive layer connected to the first conductive layer through a second contact hole penetrating the second insulating layer,
wherein:
the first conductive layer comprises a first connection metal layer, a first filling layer, and a first metal layer in contact with and covering the first connection metal layer and the first filling layer,
the first connection metal layer and the first filling layer are located inside the first contact hole, and
a thickness of the first connection metal layer and a thickness of the first filling layer are less than a height of the first contact hole.

19. The electronic device of claim 18, wherein:
the second conductive layer is in contact with a first connecting portion of the first metal layer, and
the first connecting portion overlaps with the first contact hole and the second contact hole in a direction perpendicular to the substrate.

20. The electronic device of claim 19, wherein the first conductive layer and the second conductive layer are located on a same line in the direction perpendicular to the substrate.
